(19) United States
(12) Patent Application Publication
(10) Pub. No.: US 2021/0068311 A1
(43) Pub. Date: Mar. 4, 2021

(54) HOST COMPUTER AND COMPUTER SYSTEM FOR VEHICLE

(71) Applicants: Inventec (Pudong) Technology Corporation, Shanghai City (CN); INVENTEC CORPORATION, Taipei City (TW)

(72) Inventors: Yao-Nian ZHONG, Taipei City (TW); Ping-Wei Peng, Taipei City (TW)

(21) Appl. No.: 16/565,788

(22) Filed: Sep. 10, 2019

(30) Foreign Application Priority Data
Aug. 28, 2019 (CN) 201910801005.7

(51) Int. Cl. H05K 7/20; H05K 7/14; H05K 7/04; G07C 5/08; G07C 5/00

(52) U.S. Cl. CPC H05K 7/20854; H05K 7/1431; G07C 5/008; H05K 7/20436; G07C 5/0858; H05K 7/04

(57) ABSTRACT

This disclosure relates to a host computer for vehicle including a casing, an electronic assembly, a thermal conductive block, at least one input-output interface and at least one dust-proof assembly. The casing has an opening and a heat dissipation structure respectively located at two opposite sides thereof. The casing has at least one mount hole located between the opening and the heat dissipation structure. The electronic assembly includes a circuit board, a processor and a first connector. The circuit board is located in the casing. The processor and the first connector are respectively located at two opposite sides of the circuit board. The opening exposes the first connector. The thermal conductive block is connected to the processor and the heat dissipation structure. The input-output interface is mounted at the mount hole. The dust-proof assembly is located at the mount hole to cover part of the input-output interface.

### CROSS-REFERENCE TO RELATED APPLICATIONS

This non-provisional application claims priority under 35 U.S.C. § 119(a) on Patent Application No(s). 201910801005.7 filed in China, P.R.C. on Aug. 28, 2019, the entire contents of which are hereby incorporated by reference.

### TECHNICAL FIELD

The present disclosure relates to a host computer and a computer system, more particularly to a host computer and a computer system for vehicle.

### BACKGROUND

Beside the car performance and safety, nowadays, the in-vehicle infotainment (IVI) system for providing audio or video entertainment is getting more and more attention.

As the IVI system progresses, hardware, such as processor, in the IVI system generates more heat than ever. Conventionally, the IVI system contains an in-built fan to generate air flow for cooling the processor.

### SUMMARY

According to one aspect of the present disclosure, a host computer for vehicle includes a casing, an electronic assembly, a thermal conductive block, at least one input-output interface and at least one dust-proof assembly. The casing has an opening and a heat dissipation structure respectively located at two opposite sides thereof. The casing further has at least one mount hole located between the opening and the heat dissipation structure. The electronic assembly includes a circuit board, a processor and a first connector. The circuit board is located in the casing. The processor and the first connector are respectively located at two opposite sides of the circuit board. The opening exposes the first connector. The thermal conductive block is connected to the processor and the heat dissipation structure of the casing. The at least one input-output interface is mounted at the at least one mount hole. The at least one dust-proof assembly is located at the at least one mount hole to cover part of the at least one input-output interface.

According to another aspect of the present disclosure, a computer system for vehicle includes a host computer for vehicle and an expansion module. The host computer for vehicle includes a casing, an electronic assembly, a thermal conductive block, at least one input-output interface and at least one dust-proof assembly. The casing has an opening and a heat dissipation structure respectively located at two opposite sides thereof. The casing further has at least one mount hole located between the opening and the heat dissipation structure. The electronic assembly includes a circuit board, a processor and a first connector. The circuit board is located in the casing. The processor and the first connector are respectively located at two opposite sides of the circuit board. The opening exposes the first connector. The thermal conductive block is connected to the processor and the heat dissipation structure of the casing. The at least one input-output interface is mounted at the at least one mount hole. The at least one dust-proof assembly is located at the at least one mount hole to cover part of the at least one input-output interface. The expansion module includes a housing and a function module located in the housing. The function module has a second connector detachably inserted into the first connector.

### BRIEF DESCRIPTION OF THE DRAWINGS

The present disclosure will become more fully understood from the detailed description given hereinbelow and the accompanying drawings which are given by way of illustration only and thus are not intending to limit the present disclosure and wherein:

FIG. 1 is a perspective view of a host computer for vehicle according to a first embodiment of the present disclosure;

FIG. 2 is an exploded view of the host computer in FIG. 1;

FIG. 3 is a cross-sectional view of the host computer in FIG. 1;

FIG. 4A is a partially enlarged and cross-sectional view showing that the communication connectors in FIG. 3 are not yet inserted into the first through holes of the connector panel;

FIG. 4B is a partially enlarged and cross-sectional view of the host computer in FIG. 3; and

FIG. 5 is an exploded view of a computer system for vehicle according to a second embodiment of the present disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

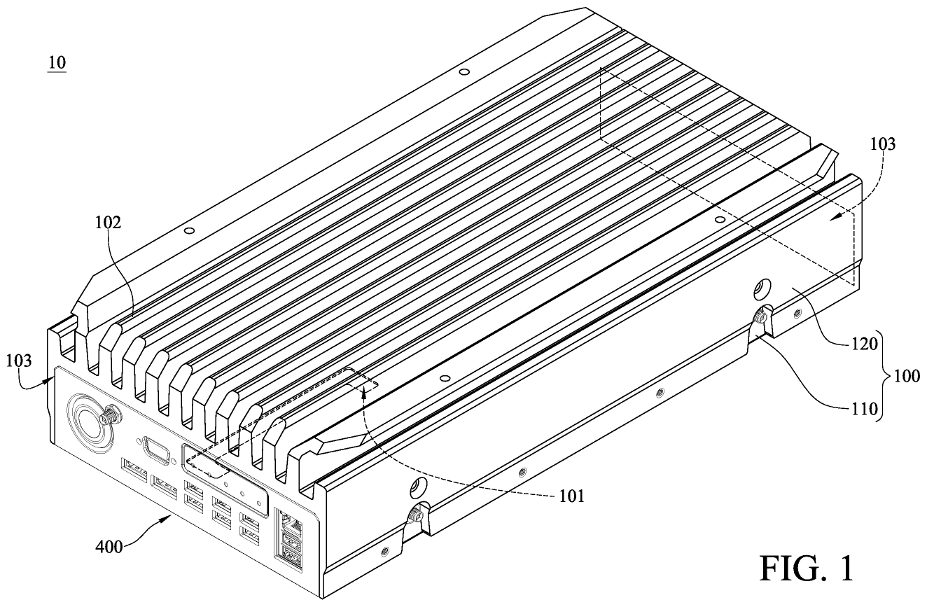

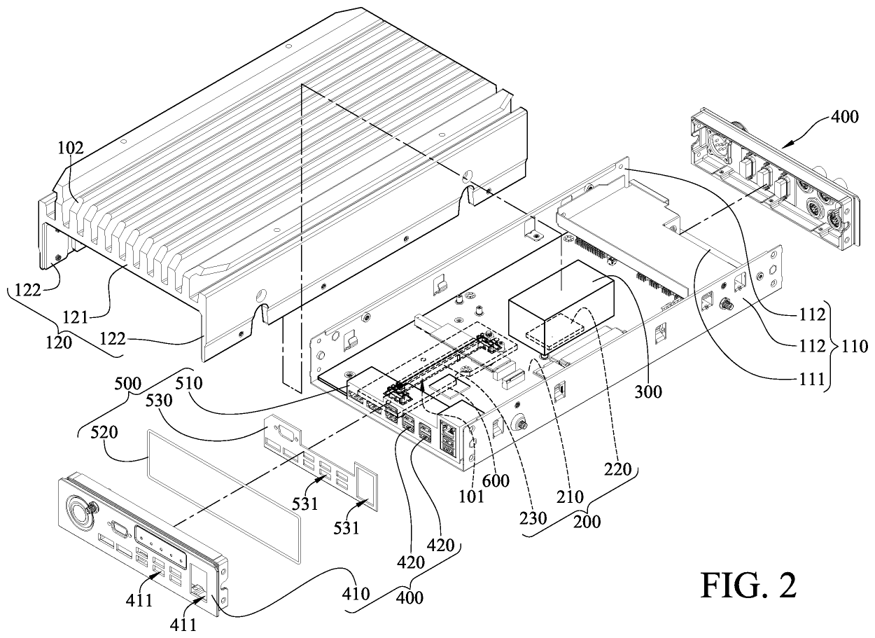

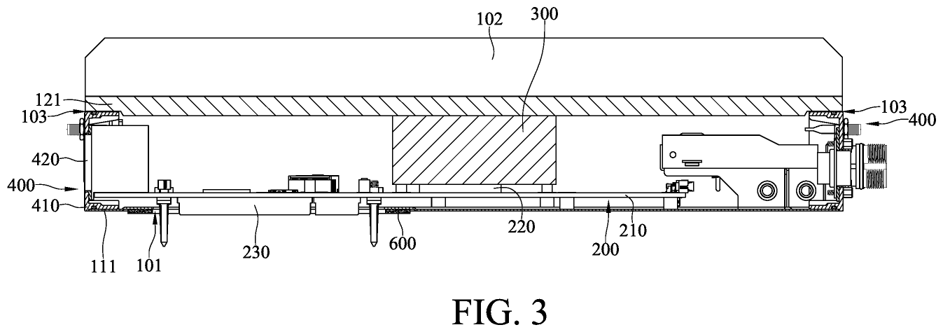

Please refer to FIG. 1 to FIG. 3. FIG. 1 is a perspective view of a host computer for vehicle according to a first embodiment of the present disclosure. FIG. 2 is an exploded view of the host computer in FIG. 1. FIG. 3 is a cross-sectional view of the host computer in FIG. 1.

This embodiment provides a host computer 10 including a casing 100, an electronic assembly 200, a thermal conductive block 300, two input-output interfaces 400 and two dust-proof assemblies 500. One of the two input-output interfaces 400 and one of the two dust-proof assemblies 500 are assembled to become one bigger assembly, while another one of the two input-output interfaces 400 and another one of the two dust-proof assemblies 500 are assembled to become another bigger assembly. These two assemblies are respectively located at two opposite sides of the casing 100. Note that the two assemblies have similar structures and only one of them is illustrated in the following paragraphs. In addition, the host computer 10 further includes a foam 600.

The casing 100 has an opening 101 and a heat dissipation structure 102 respectively located at two opposite sides thereof. The heat dissipation structure 102 may be a heatsink which can increase the area for heat dissipation. In addition, the casing 100 further has two mount holes 103 located between the opening 101 and the heat dissipation structure 102 and respectively located at two opposite sides of the casing 100.

The casing 100 may include two pieces assembled to each other. Specifically, the casing 100 includes a carrier component 110 and a cover component 120. The carrier component 110 includes a bottom plate 111 and two first side plates 112 respectively connected to two opposite sides of the bottom plate 111. The opening 101 is located on the bottom plate 111. The cover component 120 includes a cover plate 121 and two second side plates 122 respectively connected to two opposite sides of the cover plate 121. The cover plate 121 is located on and spaced apart from the bottom plate 111 so as to cover the bottom plate 111, and the heat dissipation structure 102 is located on a side of the cover plate 121 away from the bottom plate 111. The two first side plates 112 are located between and have a large area tightly in contact with the two second side plates 122, such that dust is less likely able to enter into the gaps between the two first side plates 112 and the two second side plates 122. In other word, the casing 100 provides a certain degree of protection against dust by disposing the two first side plates 112 between and tightly in contact with the two second side plates 122.

Further, when the carrier component 110 and the cover component 120 are assembled, the two mount holes 103 are formed at the two opposite sides of the casing 100.

The electronic assembly 200 includes a circuit board 210, a processor 220 and a first connector 230. The circuit board 210 is located in the casing 100 and stacked on the bottom plate 111 of the carrier component 110. The processor 220 and the first connector 230 are respectively located at two opposite sides of the circuit board 210. The processor 220 is located at a side of the circuit board 210 away from the bottom plate 111. The first connector 230 is located at a side of the circuit board 210 close to the bottom plate 111, and the opening 101 exposes the first connector 230.

The thermal conductive block 300 is, for example, a metal block having high thermal conductivity such as a copper block or a silver block. The thermal conductive block 300 has two sides respectively in thermal contact with the processor 220 and the cover plate 121 of the cover component 120. Accordingly, during the operation of the processor 220, heat generated by the processor 220 can be thermally conducted to the heat dissipation structure 102 sequentially via the thermal conductive block 300 and the cover plate 121 and then be dissipated away by the heat dissipation structure 102. Since the heat dissipation structure 102 is located on the outside of the casing 100, the heat thermally conducted to the heat dissipation structure 102 can be taken away by the air flow outside the casing 100. Therefore, the host computer 10 does not need any additional fan for drawing cool air from the outside and thereby reducing the possibility of dust entering the host computer 10.

The input-output interface 400 is disposed at one of the mount holes 103 of the casing 100. The input-output interface 400 includes a connector panel 410 and a plurality of communication connectors 420. The connector panel 410 is disposed at one of the mount holes 103 of the casing 100 and has a plurality of first through holes 411. The communication connectors 420 are respectively exposed by the first through holes 411 and are electrically connected to the circuit board 210.

The dust-proof assembly 500 is located at one of the mount holes 103 to cover part of the input-output interface 400. Specifically, the dust-proof assembly 500 includes an elastic body 510, a sealing ring 520 and a gasket 530. The elastic body 510 is made of, for example, rubber and has some properties, such as elasticity. The elastic body 510 is located in the casing 100. The communication connectors 420 are located in the elastic body 510; in other words, the communication connectors 420 are imbedded into the elastic body 510. Due to the elasticity of the elastic body 510, the gaps between the communication connectors 420 and the elastic body 510 can be minimized or eliminated, such that the elastic body 510 can be considered as a first dust-prevention feature. The sealing ring 520 is, for example, a rubber ring and has elasticity. The sealing ring 520 is sleeved on the connector panel 410 and located between and clamped by the connector panel 410 and the casing 100, and the gap between the sealing ring 520 and the connector panel 410 or the gap between the sealing ring 520 and the casing 100 can be minimized or eliminated, such that the sealing ring 520 can be considered as a second dust-prevention feature. The gasket 530 is, for example, a rubber sheet or a silicone sheet and has elasticity. The gasket 530 is located between and clamped by the connector panel 410 and the elastic body 510 and has a plurality of second through holes 531.

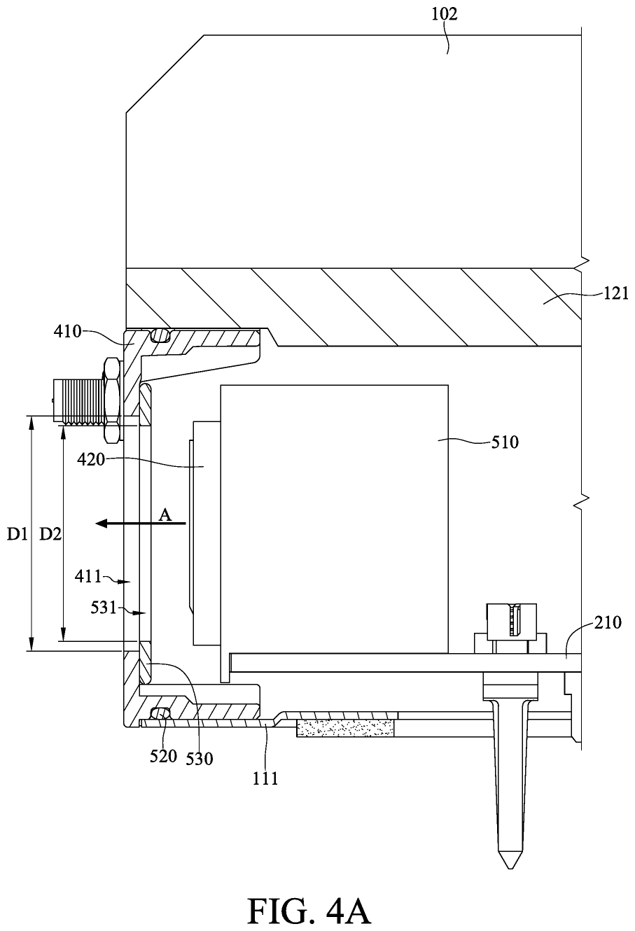

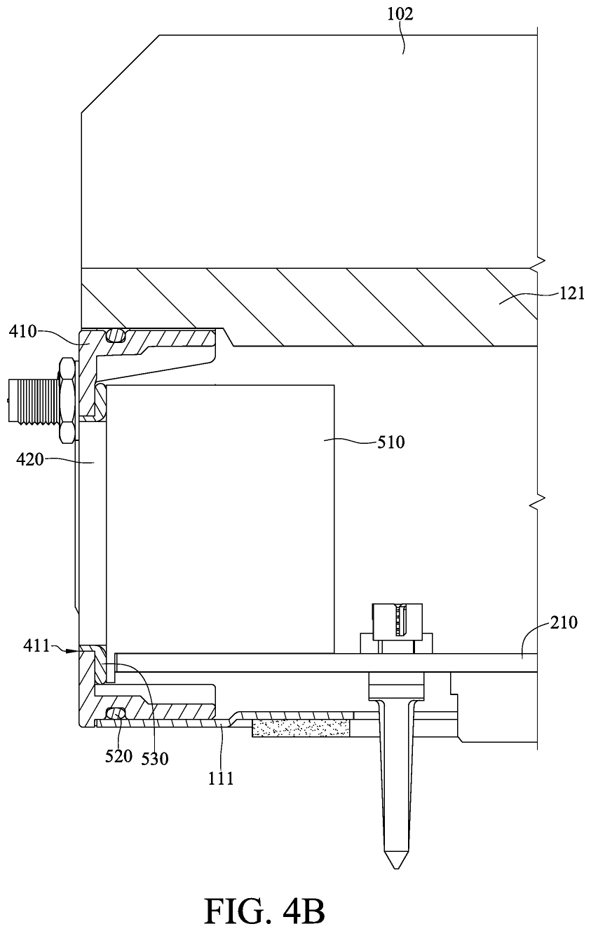

Please refer to FIG. 4A and FIG. 4B to further describe the input-output interface 400 and the dust-proof assembly 500. FIG. 4A is a partially enlarged and cross-sectional view showing that the communication connectors in FIG. 3 are not yet inserted into the first through holes of the connector panel. FIG. 4B is a partially enlarged and cross-sectional view of the host computer in FIG. 3. As shown in FIG. 4A, each of the first through holes 411 has a dimension D1, and each of the second through holes 531 has a dimension D2; the dimension D2 is smaller than the dimension D1. Part of the gasket 530 is located at the edges of the first through holes 411. The communication connectors 420 can be mounted into the first through holes 411 of the connector panel 410 in a direction A. By doing so, referring to FIG. 4B, part of the gasket 530 will be bent over by the communication connectors 420 to cover the edges of the first through holes 411. As a result, part of the gasket 530 is located between and clamped by the communication connectors 420 and the connector panel 410. Therefore, the gaps between the gasket 530 and the communication connectors 420 or the gap between the gasket 530 and the connector panel 410 can be minimized or eliminated so that the gasket 530 can be considered as a third dust-prevention feature.

With the help of the first to third dust-prevention features, dust is unlikely able to enter into the casing 100 from the mount holes 103 or the first through holes 411 of the connector panel 410. Accordingly, the electronic assembly 200 may not be affected by dust and thus the performance and lifespan of the host computer 10 can be increased.

The foam 600 is located on a side of the bottom plate 111 away from the circuit board 210. The first connector 230 is surrounded by the foam 600. The gap between the first connector 230 and the foam 600 can be minimized or eliminated so as to prevent dust from entering the casing 100.

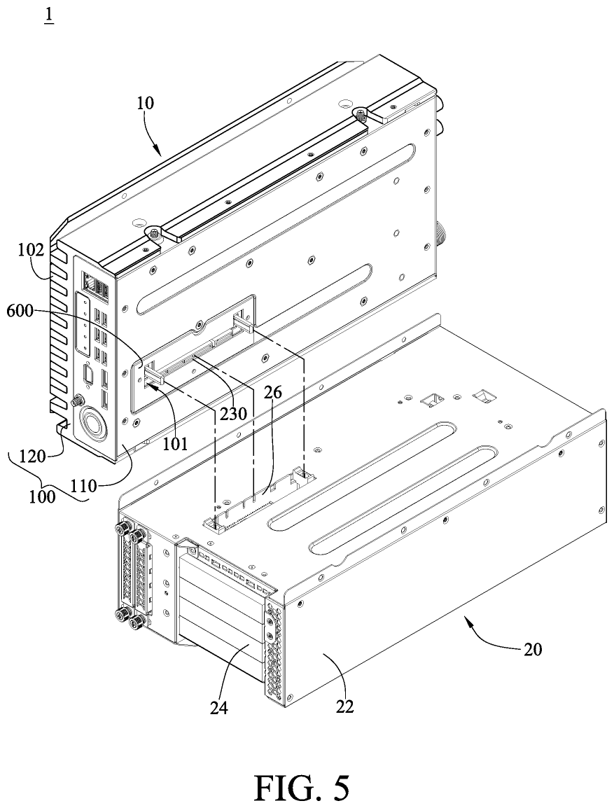

Please refer to FIG. 5. FIG. 5 is an exploded view of a computer system for vehicle according to a second embodiment of the present disclosure. A computer system 1 includes the host computer 10 and an expansion module 20. The detail of the host computer 10 has been described in the previous paragraphs and will not be repeated. Note that the descriptions related to the expansion module 20 will be illustrated hereinafter.

The expansion module 20 includes a housing 22 and a function module 24. The function module 24 is located in the housing 22. The function module 24 has a second connector 26 detachably plugged into the first connector 230 of the host computer 10. The expansion module 20 is, for example, a display device or other electronic devices of different functions. The disclosure is not limited to the type or function of the expansion module 20 and is optional to the user. Note that the expansion module 20 is also optional; in some embodiments, note that the computer system 1 may not have the expansion module 20 so as to be in a compact size.

According to the host computer for vehicle and the computer system for vehicle discussed above, during the operation of the processor, heat generated by the processor can be thermally conducted to the heat dissipation structure sequentially via the thermal conductive block and the cover plate and then be dissipated away by the heat dissipation structure. Since the heat dissipation structure is located on the outside of the casing, the heat thermally conducted to the heat dissipation structure can be taken away by the air flow outside the casing. Therefore, the host computer does not need any additional fan for drawing cool air from the outside and thereby reducing the possibility of dust entering the host computer.

With the help of the dust-proof assembly, dust is unlikely able to enter into the casing from the mount hole or the first through holes of the connector panel. Accordingly, the electronic assembly may not be affected by dust and thus the performance and lifespan of the host computer can be increased. The first to third dust-prevention features is that the gaps between the communication connectors and the elastic body, the gap between the sealing ring and the connector panel, the gap between the sealing ring and the casing, the gaps between the gasket and the communication connectors, and the gap between the gasket and the connector panel can be minimized or eliminated, such that dust is less likely able to enter into these gaps.

In addition, the first connector is surrounded by the foam, and the gap between the first connector and the foam can be minimized or eliminated so as to prevent dust from entering the casing.

In addition, the expansion module can be detachably plugged into the first connector of the host computer. Note that the expansion module is also optional; in some embodiments, note that the computer system may not have the expansion module so as to be in a compact size.

The embodiments are chosen and described in order to best explain the principles of the present disclosure and its practical applications, to thereby enable others skilled in the art best utilize the present disclosure and various embodiments with various modifications as are suited to the particular use being contemplated. It is intended that the scope of the present disclosure is defined by the following claims and their equivalents.

1. A host computer for vehicle, comprising:
a casing, having an opening and a heat dissipation structure respectively located at two opposite sides thereof, wherein the casing further has at least one mount hole located between the opening and the heat dissipation structure;
an electronic assembly, comprising a circuit board, a processor and a first connector, wherein the circuit board is located in the casing, the processor and the first connector are respectively located at two opposite sides of the circuit board, and the opening exposes the first connector;
a thermal conductive block, connected to the processor and the heat dissipation structure of the casing;
at least one input-output interface, mounted at the at least one mount hole; and
at least one dust-proof assembly, located at the at least one mount hole to cover part of the at least one input-output interface.

2. The host computer for vehicle according to claim 1, wherein the casing comprising a carrier component and a cover component, the carrier component comprises a bottom plate and two first side plates respectively connected to two opposite sides of the bottom plate, the cover component comprises a cover plate and two second side plates respectively connected to two opposite sides of the cover plate, the cover plate is located on and spaced apart from the bottom plate, the heat dissipation structure is located on a side of the cover plate away from the bottom plate, the two first side plates are located between and in contact with the two second side plates.

3. The host computer for vehicle according to claim 2, further comprising a foam located on a side of the bottom plate away from the circuit board, wherein the first connector is surrounded by the foam.

4. The host computer for vehicle according to claim 1, wherein the at least one input-output interface comprises a connector panel and a plurality of communication connectors, the connector panel is disposed at the at least one mount hole of the casing and has a plurality of first through holes, the plurality of communication connectors are electrically connected to the circuit board and respectively exposed by the plurality of first through holes.

5. The host computer for vehicle according to claim 4, wherein the at least one dust-proof assembly comprises an elastic body located in the casing, and the plurality of communication connectors are located in the elastic body.

6. The host computer for vehicle according to claim 5, wherein the at least one dust-proof assembly further comprises a sealing ring sleeved on the connector panel and clamped between the connector panel and the casing.

7. The host computer for vehicle according to claim 6, wherein the at least dust-proof assembly further comprises a gasket located between the connector panel and the elastic body and having a plurality of second through holes, each of the plurality of second through holes is smaller than each of the plurality of first through holes, part of the plurality of communication connectors are respectively located at the plurality of second through holes, and part of the gasket is located between the plurality of communication connectors and the connector panel.

8. The host computer for vehicle according to claim 1, wherein a quantity of the at least one mount hole is two, a quantity of the at least one input-output interface is two, the two mount holes are respectively located at opposite sides of the casing, and the two input-output interface are respectively disposed at the two mount holes.

9. A computer system for vehicle, comprising:
a host computer for vehicle, comprising:
a casing, having an opening and a heat dissipation structure respectively located at two opposite sides thereof, wherein the casing further has at least one mount hole located between the opening and the heat dissipation structure;
an electronic assembly, comprising a circuit board, a processor and a first connector, wherein the circuit board is located in the casing, the processor and the first connector are respectively located at two opposite sides of the circuit board, and the opening exposes the first connector;
a thermal conductive block, connected to the processor and the heat dissipation structure of the casing;
at least one input-output interface, mounted at the at least one mount hole; and
at least one dust-proof assembly, located at the at least one mount hole to cover part of the at least one input-output interface; and
an expansion module, comprising a housing and a function module located in the housing, the function module having a second connector detachably inserted into the first connector.

10. The computer system for vehicle according to claim 9, wherein the at least one input-output interface comprises a connector panel and a plurality of communication connectors, the connector panel has a plurality of first through holes, the plurality of communication connectors are electrically connected to the circuit board and respectively exposed by the plurality of first through holes, the connector panel is disposed to the casing and covers the at least one mount hole of the casing, the at least one dust-proof assembly comprises a elastic body, a sealing ring and a gasket, the elastic body is located in the casing, the plurality of communication connectors are located in the elastic body, the sealing ring is sleeved on the connector panel and clamped between the connector panel and the casing, the gasket is located between the connector panel and the elastic body and has a plurality of second through holes, each of the plurality of second through holes is smaller than each of the plurality of first through holes, part of the plurality of communication connectors are respectively located at the plurality of second through holes, and part of the gasket is located between the plurality of communication connectors and the connector panel.
